(19) United States
(12) Patent Application Publication
(10) Pub. No.: US 2007/0139080 A1
(43) Pub. Date: Jun. 21, 2007

(54) Single-ended CMOS signal interface to differential signal receiver loads

(76) Inventor: George C. Tang, Cupertino, CA (US)

Correspondence Address: Pete Scott, Senior Corporate Counsel;LSI Logic Corporation, Legal Department - IP, 1621 Barber Lane, MS D-106, Milpitas, CA, 95035, US

(21) Appl. No.: 11/314,856

(22) Filed: Dec. 20, 2005

(51) Int. Cl. H03K 19/094

(52) U.S. Cl. 326/87

(57) ABSTRACT

The interface of a single-ended CMOS type signal to differential signal loads includes a LVDS load having a +Vin input and a −Vin input, a CMOS circuit having an output signal line, and a resistor Rt connected to the output signal line and ground. A 2.5 volt source line is connected through a resistor R1 to the −Vin input of the LVDS load, the output signal line is connected directly to the +Vin input of the LVDS load, and a resistor R2 and capacitor C1 re connected in parallel between R1 and the −Vin input and ground.

### FIELD OF THE INVENTION

The present invention is generally related to signal drivers and receivers as used in the communications industry. More particularly, the present invention is related to the interface that will convert a single-ended CMOS signal to differential signaling for differential signal loads, thus resulting in lower cost, lower delay and less jitter, yet producing higher bandwidth and low phase-offset.

### BACKGROUND

Drivers are used in communications. Because different circuits utilize different drivers for the transmitters and receivers, it is necessary to interface diverse driver types with varying loads. All drivers have different voltage swings and load end termination. Because there are so many types of communications drivers, there is a need for drivers that can interface with varying loads.

Delays are experienced whenever a single-ended signal, such as a CMOS signal output, is interfaced with a differential signal, such as an LVDS or PCML receiver loads. CMOS signal outputs are provided in the form of single-ended outputs; but a differential signal load, such as an LVDS, has a differential input represented by two inputs, +Vin and −Vin. When a single ended signal (CMOS) must communicate with a differential signal, phase misalignment can be experienced.

Referring to FIG. 1, labeled as “prior art”, the system 100 that is illustrated includes a CMOS circuit 110 having a single-ended output interfaced with the two inputs, +Vin and −Vin, of a typical LVDS load termination 120. The CMOS output being digital typically includes the use of two independent drivers, A1 and A2, forming independent connections to the LVDS inputs, +Vin and −Vin. An inverted driver is used to drive the −Vin input of the LVDS load. A design requiring two more drivers in-between the CMOS and LVDS receiver is what is typically done by digital designers to accomplish the interface.

The problem with the circuit shown in FIG. 1 is that the use of a positive and negative driver can cause a signaling delay. The output signal from the CMOS circuit can also experience a mismatch or phase shift or misalignment with the LVDS load during signaling. Furthermore, the design in FIG. 1 will cause a price increase because of the introduction of additional logic to accomplish the conversion from a single ended input to the differential output. What is needed is a solution that will improve performance where single ended CMOS drivers must operate with differential loads.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings and abstract as a whole.

It is therefore one aspect of the present invention to provide for an improved interface of a single-ended CMOS type signal to differential signal loads.

It is therefore one aspect of the present invention to provide an interface that will convert a single-ended CMOS signal to differential signaling for differential signal loads, thus resulting in lower cost, lower delay and less jitter, yet producing higher bandwidth and low phase-offset.

In accordance with the preferred embodiment, an improved driver circuit corrects for delays, phase misalignment and impedance mismatch by utilizing an Rt=50 ohms, various values of R1 and R2 such that 1/3<(R1/R2)<3, and C1 in the range of 1 pF through 1 uF.

In accordance with the preferred embodiment, the preferred driver circuit corrects for delays, phase misalignment and impedance mismatch by utilizing an Rt=50 ohms, R1=1000 ohm range, and C1 in the range of 1 pf through 1 uF.

### BRIEF DESCRIPTION OF THE DRAWINGS

The accompanying figures, in which like reference numerals refer to identical or functionally similar elements throughout the separate views and which are incorporated in and form part of the specification, further illustrate embodiments of the present invention.

FIG. 1 labeled as “prior art” illustrates a block diagram of current CMOS to a differential output driver load.

FIG. 2 illustrates the a preferred embodiment in which introduces two resistors, labeled R1 and R2, and a capacitor, C1, are used in place of two amplifiers previously used to accomplish the CMOS differential output driver interface.

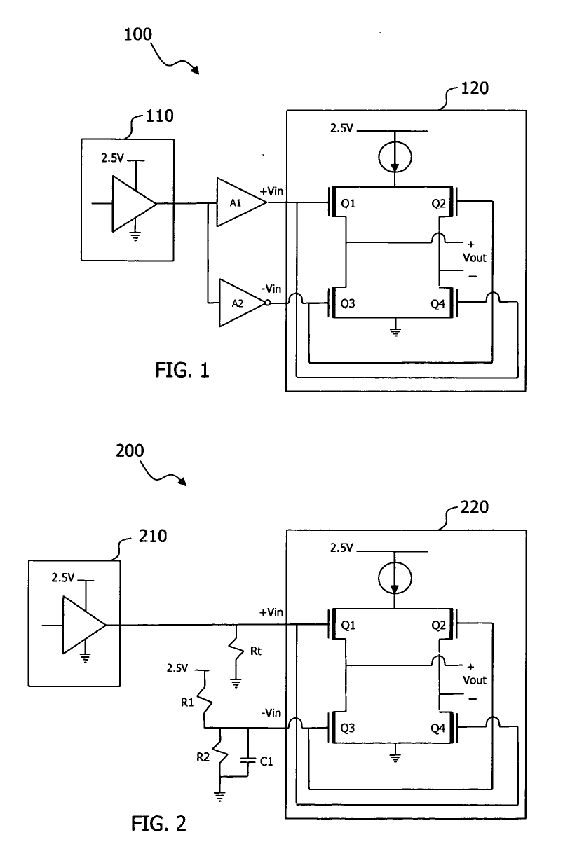

### DETAILED DESCRIPTION

The particular values and configurations discussed in these non-limiting examples can be varied and are cited merely to illustrate embodiments of the present invention and are not intended to limit the scope of the invention.

As stated in the background, the introduction positive and negative drivers between CMOS and LVDS loads can cause a signaling delay. The output signal from the CMOS circuit can also experience a mismatch or phase shift or misalignment with the LVDS load during signaling.

Referring to FIG. 2, a simplified circuit 200 illustrates a solution to problems previously encountered by CMOS to differential circuit interfaces. The solution introduces two resistors, labeled R1 and R2, and a capacitor, C1, in place of the two amplifiers. The three circuit elements, R1, R2 and C1, are used to fix the voltage on the negative input of the LVDS. When the negative input on the LVDS is fixed at a certain bias voltage, then the LVDS input will receive the differential signal (up/down) as the CMOS output switches up and down. The LVDS output will also switch up/down in response to the input. The circuit 200 shows the CMOS 210 providing direct input to +Vin of the LVDS load 220. A resistor Rt is connected to the signal line connecting the CMOS circuit and the +Vin input of the LVDS, and the Rt resistor is then grounded. The −Vin input of the LVDS load 220 taken between 2.5V input running through R1 and an RC combination of R2 and C1 which are both grounded.

This invention implements an analog solution in a digital world. This mixed solution is low in cost and has not been implemented in communications thus far and resolve the problem experience in today's mixed signal communications industry where mixed circuitry (analog and digital) must be used.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. An interface of a single-ended CMOS type signal to a differential signal load, comprising:
an LVDS load having a +Vin input and a −Vin input;
a CMOS circuit having an output signal line, said output signal line connected directly to the +Vin input of the LVDS load, and a resistor Rt connected to the output signal line and ground; and
a 2.5 volt source line connected through a resistor R1 to the −Vin input of the LVDS load, and a resistor R2 and C1 connected in parallel between R1 and the −Vin input and ground.
